(19) United States
(12) Patent Application Publication
(10) Pub. No.: US 2026/0150527 A1
(43) Pub. Date: May 28, 2026

(54) Display Device

(71) Applicant: LG Display Co., Ltd., Seoul (KR)

(72) Inventors: Jaeyoung Lee, Seoul (KR); JiYoung Kim, Paju-si (KR); Mingeun Choi, Asan-si (KR)

(21) Appl. No.: 19/317,587

(22) Filed: Sep. 3, 2025

(30) Foreign Application Priority Data
Nov. 28, 2024 (KR) 10-2024-0174045

(51) Int. Cl. H10K 59/124; H10K 59/122

(52) U.S. Cl. CPC H10K 59/124; H10K 59/122

(57) ABSTRACT

A display device according to an embodiment of the present disclosure includes a planarization film disposed above a substrate and having a protruding portion, an anode disposed on a top surface of the protruding portion of the planarization film and including at least first and second areas having different thicknesses, an organic layer disposed on the anode and a cathode disposed on the organic layer corresponding to the top surface and a lateral portion of the protruding portion, thereby improving light extraction efficiency by increasing a light emission distribution of extracted light.

### CROSS-REFERENCE TO RELATED APPLICATIONS

This application claims the priority of Korean Patent Application No. 10-2024-0174045 filed on Nov. 28, 2024, in the Korean Intellectual Property Office, the disclosure of which is incorporated herein by reference.

### BACKGROUND

### Field

The present specification relates to a display device.

### Description of the Related Art

Display devices, which visually display electrical information signals, are being rapidly developed in accordance with the entry into the information era. Various studies are continuously being conducted to develop a variety of display devices which are thin and lightweight, consume low power, and have improved performance.

Representative display devices may include a liquid crystal display device (LCD), a field emission display device (FED), an electrowetting display device (EWD), an organic light-emitting display device (OLED), and the like.

An electroluminescent display device, as a representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in color implementation, response speed, viewing angle, and contrast ratio (CR).

In the electroluminescent display device, a light-emitting element is configured by disposing a plurality of organic layers including light-emitting layers between two electrodes that are an anode electrode and a cathode electrode. For example, when positive holes are injected into the light-emitting layer from the anode electrode and electrons are injected into the light-emitting layer from the cathode electrode, the injected electrons and the injected positive holes are recombined in the light-emitting layer and emit light while producing excitons.

Meanwhile, the electroluminescent display device has a problem in that among the light beams emitted from the light-emitting layer, some are trapped in a display panel without propagating outside the display panel, which degrades the light extraction efficiency and luminous efficiency of the electroluminescent display device.

The amount of light emitted from the light-emitting layer increases as the amount of current applied to the electroluminescent display device increases. Therefore, a larger amount of current may be applied to the light-emitting layer to further improve the luminance of the electroluminescent display device. However, the increase in the amount of current increases power consumption and decreases the lifespan of the electroluminescent display device.

### SUMMARY

An object to be achieved by the present disclosure is to provide a display device capable of improving efficiency by improving light extraction efficiency.

Another object to be achieved by the present disclosure is to provide a display device capable of further increasing a lifespan by improving light extraction efficiency.

Objects of the present disclosure are not limited to the above-mentioned objects, and other objects, which are not mentioned above, can be clearly understood by those skilled in the art from the following descriptions.

In order to achieve the above-mentioned objects, a display device according to an embodiment of the present disclosure may include a planarization film disposed above a substrate and having a protruding portion, an anode disposed on a top surface of the protruding portion of the planarization film and including at least first and second areas having different thicknesses, an organic layer disposed on the anode and a cathode disposed on the organic layer corresponding to the top surface and a lateral portion of the protruding portion.

Other detailed matters of the exemplary embodiments are included in the detailed description and the drawings.

The present disclosure may provide the display device including the side mirror structure of the cathode and having improved light extraction efficiency.

The present disclosure may provide the display device in which the thickness of the end of the anode is decreased to increase the light emission distribution of the extracted light, thereby further improving the light extraction efficiency.

In this case, as the luminance is improved, power consumption may be reduced, the amount of use of fossil fuel for producing power may be reduced by the low power consumption, and the emission of greenhouse gases may be reduced, such that ESG (Environment/Social/Governance) may be implemented.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a configuration view exemplarily illustrating a display device according to the present disclosure;

FIG. 2 is a top plan view schematically illustrating the display device according to the present disclosure;

FIG. 3 is a top plan view illustrating a pixel structure of a display panel according to a first embodiment of the present disclosure;

FIG. 4 is a cross-sectional view taken along line A-A′ in FIG. 3;

FIG. 5 is a cross-sectional view taken along line B-B′ in FIG. 3;

FIGS. 6A and 6B are graphs illustrating electroluminescence spectra of a comparative example;

FIGS. 7A and 7B are graphs illustrating electroluminescence spectra of Experimental Example 1;

FIGS. 8A and 8B are graphs illustrating electroluminescence spectra of Experimental Example 2;

FIGS. 9A and 9B are graphs illustrating electroluminescence spectra of Experimental Example 3;

FIGS. 10A and 10B are graphs illustrating electroluminescence spectra of Experimental Example 4;

FIG. 11 is a table showing intensities of electroluminescence spectra with respect to incident angles of the comparative example and Experimental Examples 1 to 4;

FIG. 12 is a view illustrating a simulation result showing light emission in accordance with light emission incident angles;

FIGS. 13A to 13E are cross-sectional views sequentially illustrating a part of a process of manufacturing the display panel in FIG. 5; and

FIG. 14 is a cross-sectional view illustrating a display panel according to a second embodiment of the present disclosure.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

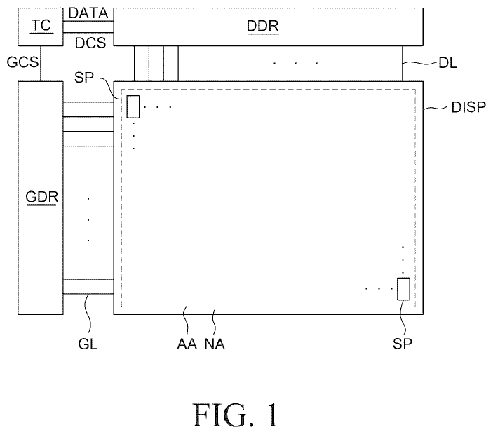

FIG. 1 is a configuration view exemplarily illustrating a display device according to the present disclosure.

Display devices according to embodiments of the present disclosure may include a display device, a lighting device, an electroluminescent display device, and the like. Hereinafter, for convenience of description, the description will be focused on the display device. However, the following description will also be equally applied to various types of display devices such as the lighting device and the electroluminescent display device.

With reference to FIG. 1, the display device according to the embodiments of the present disclosure may include a display panel DISP configured to display images or output light, and a drive circuit configured to operate the display panel DISP.

The display panel DISP includes a plurality of data lines DL and a plurality of gate lines GL. A plurality of subpixels SP defined by the plurality of data lines DL and the plurality of gate lines GL may be arranged in a matrix type.

The plurality of data lines DL and the plurality of gate lines GL of the display panel DISP may be disposed to intersect one another. For example, the plurality of gate lines GL may be arranged in rows or columns, and the plurality of data lines DL may be arranged in columns or rows. Hereinafter, for convenience of description, it is assumed that the plurality of gate lines GL is disposed in rows, and the plurality of data lines DL is disposed in columns.

In addition to the plurality of data lines DL and the plurality of gate lines GL, other types of signal lines may be disposed on the display panel DISP depending on subpixel structures and the like. For example, a drive voltage line, a reference voltage line, a common voltage line, or the like may be further disposed.

The display panel DISP may be one of various types of panels such as a liquid crystal display (LCD) panel and an organic light emitting diode (OLED) panel.

The types of signal lines disposed on the display panel DISP may vary depending on subpixel structures, panel types, and the like. In addition, in the present disclosure, the signal line may conceptually include an electrode to which a signal is applied.

The display panel DISP may include a display area AA that displays images, and a non-display area NA that is disposed at an outer periphery of the display area AA and displays no image. In this case, the non-display area NA is also referred to as a bezel area.

The plurality of subpixels SP for displaying images may be disposed in the display area AA.

A pad part may be disposed in the non-display area NA and electrically connected to a data driver DDR. A plurality of data link lines for connecting the pad part and the plurality of data lines DL may be disposed in the non-display area NA. In this case, the plurality of data link lines may be portions of the plurality of data lines DL that extend to the non-display area NA. Alternatively, the plurality of data link lines may be separate patterns electrically connected to the plurality of data lines DL.

In addition, gate drive-related lines may be disposed in the non-display area NA and transmit voltages, which are required to operate gates, to a gate driver GDR through the pad part electrically connected to the data driver DDR. For example, the gate drive-related lines may include a clock line for transmitting a clock signal, a gate voltage line for transmitting gate voltages, and a gate drive control signal line for transmitting various types of control signals required to generate scan signals. Unlike the gate line GL disposed in the display area AA, the gate drive-related lines may be disposed in the non-display area NA.

In addition, for example, the drive circuit may include the data driver DDR configured to operate the plurality of data lines DL, the gate driver GDR configured to operate the plurality of gate lines GL, and a timing controller TC configured to control the data driver DDR and the gate driver GDR.

As described above, the data driver DDR may operate the plurality of data lines DL by outputting data voltages to the plurality of data lines DL.

In addition, the gate driver GDR may operate the plurality of gate lines GL by outputting scan signals to the plurality of gate lines GL.

For example, the timing controller TC may control driving operations of the data driver DDR and the gate driver GDR by supplying various types of control signals DCS and GCS required for the driving operations of the data driver DDR and the gate driver GDR. The timing controller TC may supply image data DATA to the data driver DDR.

The timing controller TC may start scanning in accordance with the timing implemented in each frame, output the image data DATA made by converting input image data, which are inputted from the outside, into data signal types used for the data driver DDR, and control data operations at the appropriate time in accordance with the scanning.

For example, to control the data driver DDR and the gate driver GDR, the timing controller TC may receive timing signals such as a vertical synchronizing signal, a horizontal synchronizing signal, an input data enable signal, and a clock signal from the outside, generate various types of control signals, and output the control signals to the data driver DDR and the gate driver GDR.

For example, to control the gate driver GDR, the timing controller TC may output various types of gate control signals GCS including a gate start pulse GSP, a gate shift clock GSC, a gate output enable signal GOE, and the like.

In addition, to control the data driver DDR, the timing controller TC may output various types of data control signal DCS including a source start pulse SSP, a source sampling clock SSC, a source output enable signal SOE, and the like.

The timing controller TC may be implemented as a component provided separately from the data driver DDR or implemented as an integrated circuit by being integrated with the data driver DDR.

The data driver DDR may receive the image data DATA from the timing controller TC and operate the plurality of data lines DL by supplying data voltages to the plurality of data lines DL. The data driver DDR is also referred to as a source driver.

The data driver DDR may transmit or receive various types of signals to or from the timing controller TC through various types of interfaces.

In addition, the gate driver GDR may sequentially operate the plurality of gate lines GL by sequentially supplying scan signals to the plurality of gate lines GL. In this case, the gate driver GDR is also referred to as a scan driver.

The gate driver GDR may sequentially supply the scan signals with ON-voltages or OFF-voltages to the plurality of gate lines GL under the control of the timing controller TC.

When a particular gate line is opened by the gate driver GDR, the data driver DDR may convert the image data DATA, which are received from the timing controller TC, into analog data voltages and supply the analog data voltages to the plurality of data lines DL.

The data driver DDR may be positioned only at one side of the display panel DISP. In some instances, the data drivers DDR may be positioned at two opposite sides of the display panel DISP in accordance with driving methods, panel designing methods, and the like. For example, the data driver DDR may be positioned at an upper or lower side of the display panel DISP. Alternatively, the data drivers DDR may be positioned at both the upper and lower sides of the display panel DISP.

The gate driver GDR may be positioned only at one side of the display panel DISP. In some instances, the gate drivers GDR may be positioned at two opposite sides of the display panel DISP in accordance with driving methods, panel designing methods, and the like. For example, the gate driver GDR may be positioned at a left or right side of the display panel DISP. Alternatively, the gate drivers GDR may be positioned at the left and right sides of the display panel DISP.

The data driver DDR may be implemented to include one or more source driver integrated circuits SDIC.

For example, the source driver integrated circuits may each include a shift register, a latch circuit, a digital-analog converter (DAC), an output buffer, and the like. In some instances, the data driver DDR may further include one or more analog-digital converters ADC.

In addition, for example, the source driver integrated circuit may be connected to a bonding pad of the display panel DISP as a tape-automated bonding (TAB) type or a chip-on-glass (COG) type. Alternatively, the source driver integrated circuit may be disposed directly on the display panel DISP. In some instances, the source driver integrated circuits may be disposed by being integrated on the display panel DISP. In addition, the source driver integrated circuits may each be implemented as a chip-on-film (COF) type. In this case, the source driver integrated circuits may each be mounted on a circuit film and electrically connected to the data line DL of the display panel DISP through a circuit film.

The gate driver GDR may be configured as a plurality of gate drive circuits. In this case, the plurality of gate drive circuits may respectively correspond to the plurality of gate lines GL.

For example, the gate drive circuits may each include a shift register, a level shifter, and the like.

The gate drive circuit may be connected to the bonding pad of the display panel DISP as a tape-automated bonding (TAB) type or a chip-on-glass (COG) type. In addition, the gate drive circuits may each be implemented as a chip-on-film (COF) type. In this case, the gate drive circuits may each be mounted on the circuit film and electrically connected to the gate line GL of the display panel DISP through the circuit film. In addition, the gate drive circuits may each be implemented as a gate-in-panel (GIP) type and embedded in the display panel DISP. For example, the gate drive circuits may each be formed directly on the display panel DISP.

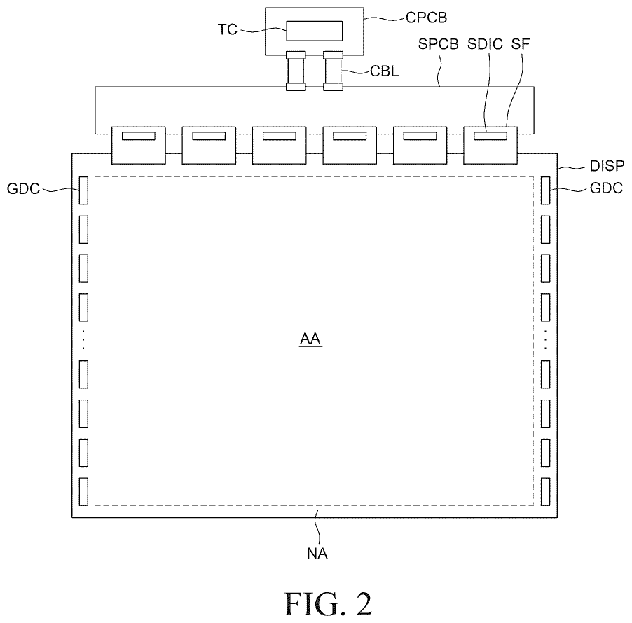

FIG. 2 is a top plan view schematically illustrating the display device according to the present disclosure.

With reference to FIG. 2, in the display device according to the embodiments of the present disclosure, the data driver may be implemented as a chip-on-film type among the above-mentioned various types (TAB, COG, COF, etc.), and the gate driver may be implemented as a gate-in-panel (GIP) type among various types (TAB, COG, COF, GIP, etc.). However, the present disclosure is not limited thereto, and various types may be provided.

The data driver may be implemented as one or more source driver integrated circuits SDIC. FIG. 2 illustrates an example in which the data driver is implemented as a plurality of source driver integrated circuits SDIC. However, the present disclosure is not limited thereto.

In case that the data driver is implemented as the COF type, the source driver integrated circuits SDIC, which constitutes the data driver, may be mounted on a source-side circuit film SF.

For example, one side of the source-side circuit film SF may be electrically connected to the pad part (an assembly of pads) disposed in the non-display area NA of the display panel DISP.

In addition, lines for electrically connecting the source driver integrated circuit SDIC and the display panel DISP may be disposed on the source-side circuit film SF.

The display device may include one or more source printed circuit boards SPCB and a control printed circuit board CPCB for mounting control components and various types of electric devices in order to circuit-connect the plurality of source driver integrated circuits SDIC and the other devices.

For example, one side of the source-side circuit film SF on which the source driver integrated circuit SDIC is mounted may be electrically connected to the non-display area NA of the display panel DISP, and the other side of the source-side circuit film SF may be electrically connected to the source printed circuit board SPCB.

In addition, the timing controller TC may be disposed on the control printed circuit board CPCB and control the operation of the data driver and the operation of the gate driver.

A power management integrated circuit PMIC and the like may be further disposed on the control printed circuit board CPCB and supply various types of voltages or electric currents to the display panel DISP, the data driver, the gate driver, and the like or control various types of voltages or electric currents to be supplied.

The source printed circuit board SPCB and the control printed circuit board CPCB may be circuit-connected by at least one connection member CBL.

For example, the connection member CBL may be a flexible printed circuit (FPC), a flexible flat cable (FFC), or the like.

For example, the one or more source printed circuit boards SPCB and the control printed circuit board CPCB may be implemented by being integrated into a single printed circuit board.

In case that the gate driver is implemented as a gate-in-panel (GIP) type, a plurality of gate drive circuits GDC included in the gate driver may be formed directly on the non-display area NA of the display panel DISP.

The gate drive circuit GDC may each output a corresponding scan signal to a corresponding gate line disposed in the display area AA of the display panel DISP.

The plurality of gate drive circuits GDC disposed on the display panel DISP may receive various types of signals (a clock signal, a high-level gate voltage VGH, a low-level gate voltage, a start signal, a reset signal, etc.), which are required to generate scan signals, through the gate drive-related lines disposed in the non-display area NA.

The gate drive-related lines disposed in the non-display area NA may be electrically connected to the source-side circuit film SF disposed to be closest to the plurality of gate drive circuits GDC.

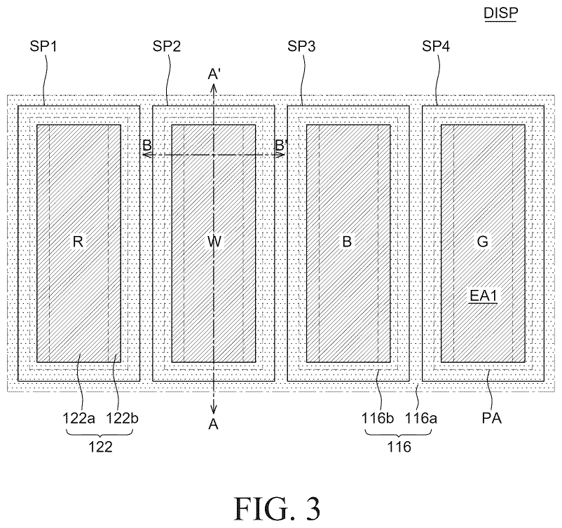

FIG. 3 is a top plan view illustrating a pixel structure of the display panel according to a first embodiment of the present disclosure.

FIG. 3 illustrates a part of the display panel DISP on which four subpixels SP1, SP2, SP3, and SP4 are disposed as an example. FIG. 3 exemplarily illustrates anodes 122 configured to define main light-emitting areas EA1, and a second planarization film 116 including protruding areas PA.

With reference to FIG. 3, the display panel DISP according to the first embodiment of the present disclosure may include a pixel area in which the plurality of subpixels SP1, SP2, SP3, and SP4 are present, and a line area in which various types of signal lines are disposed around the pixel area.

The first to fourth subpixels SP1, SP2, SP3, and SP4 may be disposed in the pixel area.

For example, the first subpixel SP1 may be a red subpixel R.

For example, the second subpixel SP2 may be a white subpixel W.

For example, the third subpixel SP3 may be a blue subpixel B.

For example, the fourth subpixel SP4 may be a green subpixel G. However, the present disclosure is not limited to the arrangement of the plurality of subpixels SP1, SP2, SP3, and SP4.

For example, the first subpixel SP1, the second subpixel SP2, the third subpixel SP3, and the fourth subpixel SP4 may each have a polygonal shape such as a rectangular shape or a square shape. However, the present disclosure is not limited thereto. The first subpixel SP1, the second subpixel SP2, the third subpixel SP3, and the fourth subpixel SP4 may each have various shapes such as a circular shape or an elliptical shape. In this case, the shape of the anode 122 (specifically, a first area 122a of the anode 122) is defined as the shape of each of the subpixels SP1, SP2, SP3, and SP4. However, the present disclosure is not limited thereto.

FIG. 3 illustrates an example in which one first subpixel SP1, one second subpixel SP2, one third subpixel SP3, and one fourth subpixel SP4 are collected to constitute one pixel. However, the present disclosure is not limited thereto.

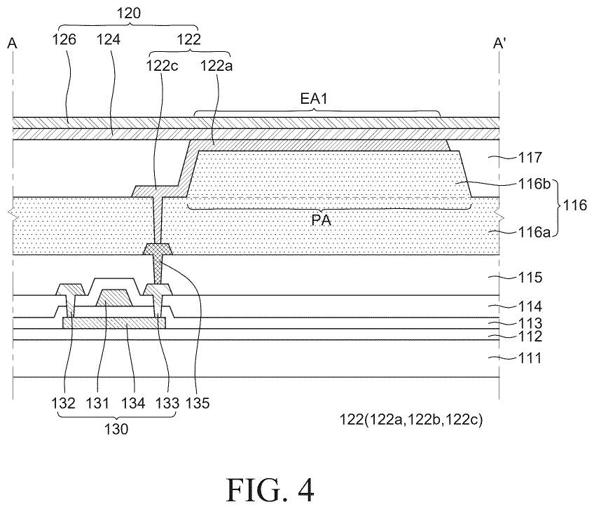

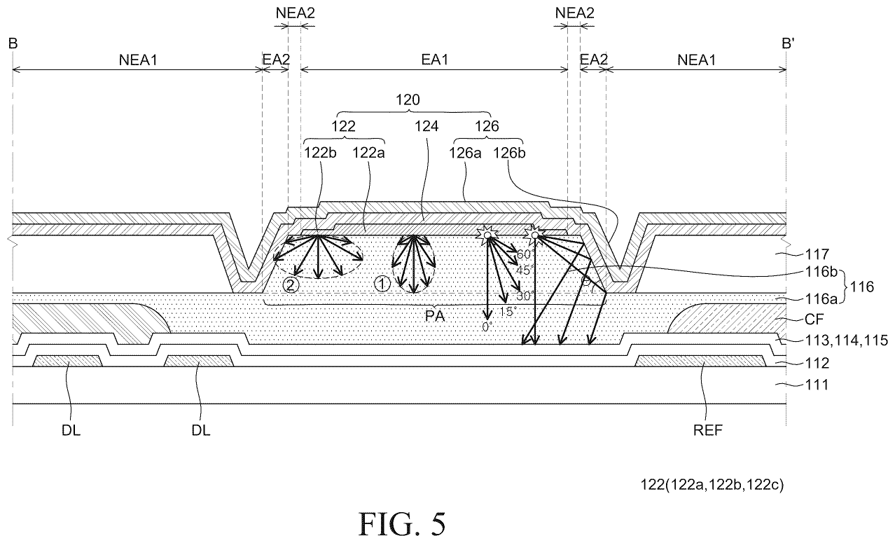

Meanwhile, in the present disclosure, a reflection area is added by a side mirror (SM) structure of a cathode in addition to the main light-emitting area EA1, such that the light-emitting area may be enlarged in comparison with each of the subpixels SP1, SP2, SP3, and SP4. The side mirror structure of the cathode will be described in detail with reference to FIGS. 4 and 5.

In the first embodiment of the present disclosure, the areas 122a and 122b are different in thickness of the anode 122, which may improve light emission distribution of extracted light. Therefore, light extraction efficiency may be further improved. This configuration will be described below in detail with reference to FIGS. 4 and 5.

FIG. 4 is a cross-sectional view taken along line A-A′ in FIG. 3.

FIG. 5 is a cross-sectional view taken along line B-B′ in FIG. 3.

FIG. 4 illustrates a part of a cross-section taken by cutting the white subpixel of the display panel according to the first embodiment of the present disclosure in an upward/downward direction.

FIG. 5 illustrates a part of a cross-section taken by cutting the white subpixel of the display panel according to the first embodiment of the present disclosure in a leftward/rightward direction.

For convenience of description, FIGS. 4 and 5 do not illustrate components disposed above a light-emitting element 120. However, the present disclosure may include an encapsulation structure disposed above the light-emitting element 120.

With reference to FIGS. 4 and 5, a buffer layer 112, such as a multi-buffer layer or a lower buffer layer, may be disposed above a substrate 111.

Recently, the flexible substrate 111 has been made of a flexible material such as plastic having flexibility.

The substrate 111 may be provided in the form of a film made of one selected from a group consisting of polyester-based polymer, silicon-based polymer, acrylic polymer, polyolefin-based polymer, and a copolymer thereof.

The substrate 111 may include a first substrate, a second substrate, and an insulation film. The insulation film may be disposed between the first substrate and the second substrate. As described above, the substrate 111 may include the first substrate, the second substrate, and the insulation film, thereby suppressing moisture permeation. For example, the first substrate and the second substrate may each be a polyimide (PI) substrate.

Various signal lines, such as the data line DL, a reference voltage line REF, or a common voltage line, may be disposed on the substrate 111. However, the present disclosure is not limited thereto. The data line DL, the reference voltage line REF, or the common voltage line may be disposed on the buffer layer 112. For example, the data line DL, the reference voltage line REF, or the common voltage line may be disposed in a first non-light-emitting area NEA1.

For example, the multi-buffer layer may delay the diffusion of moisture or oxygen permeating into the substrate 111. The multi-buffer layer may be configured by alternately stacking silicon nitride (SiNx) and silicon oxide (SiOx) at least once.

For example, the lower buffer layer may serve to protect a semiconductor layer 134 and suppress various types of defects introduced from the substrate 111.

For example, the lower buffer layer may be made of amorphous silicon, silicon nitride (SiNx), silicon oxide (SiOx), or the like.

A thin-film driving transistor 130 may be disposed above the buffer layer 112.

Specifically, the semiconductor layer 134 may be disposed in the first non-light-emitting area NEA1 provided above the substrate 111.

For example, the semiconductor layer 134 may be made of polycrystalline semiconductor and have a channel area, a source area, and a drain area. However, the present disclosure is not limited thereto. The semiconductor layer 134 may be made of amorphous silicon or oxide semiconductor.

A gate insulation film 113 may be disposed on the semiconductor layer 134.

The gate insulation film 113 may be configured as a single layer or multilayer made of silicon nitride (SiNx) or silicon oxide (SiOx). However, the present disclosure is not limited thereto.

A gate line may be disposed in a first direction on the gate insulation film 113, and a gate electrode 131 connected to the gate line may be disposed. However, the present disclosure is not limited thereto. The gate line, together with the data line DL, may be disposed on the substrate 111.

The gate electrode 131 may be disposed on the gate insulation film 113 and overlap the semiconductor layer 134.

For example, the gate electrode 131 and the gate line may each be configured as a single layer or multilayer made of copper (Cu), aluminum (Al), molybdenum (Mo), chromium (Cr), gold (Au), titanium (Ti), nickel (Ni), neodymium (Nd), or the like, which are conductive metal, or an alloy thereof. However, the present disclosure is not limited thereto.

An interlayer insulation film 114 may be disposed on the gate electrode 131 and cover the gate electrode 131.

For example, the interlayer insulation film 114 may be configured as a single layer or multilayer made of silicon nitride (SiNx) or silicon oxide (SiOx). However, the present disclosure is not limited thereto.

In this case, contact holes through which two opposite ends of the semiconductor layer 134 are exposed may be formed by selectively removing a partial area of the interlayer insulation film 114 and a partial area of the gate insulation film 113.

In addition, a source electrode 132 and a drain electrode 133, which are respectively connected to two opposite ends of the semiconductor layer 134, may be disposed on the interlayer insulation film 114.

A protective film may be disposed above the source electrode 132 and the drain electrode 133. The protective film may be excluded in some instances.

The protective film may be configured as a single layer or multilayer made of silicon nitride (SiNx) or silicon oxide (SiOx). However, the present disclosure is not limited thereto.

The planarization films 115 and 116 may be disposed on the protective film.

The planarization films 115 and 116 may have a multilayer structure including at least two layers. For example, the planarization films 115 and 116 may include a first planarization film 115 and the second planarization film 116. The first planarization film 115 may be disposed to cover the thin-film driving transistor 130 and disposed so that the source electrode 132 or the drain electrode 133 of the thin-film driving transistor 130 is partially exposed.

The first planarization film 115 may have a thickness of about 2 μm. However, the present disclosure is not limited thereto.

The first planarization film 115 may be an overcoat layer.

For example, a connection electrode 135 may be disposed on the first planarization film 115 and electrically connect the thin-film driving transistor 130 and the light-emitting element 120.

The connection electrode 135 may be made of a material such as copper (Cu), aluminum (Al), molybdenum (Mo), chromium (Cr), gold (Au), titanium (Ti), nickel (Ni), neodymium (Nd), or an alloy thereof. However, the present disclosure is not limited thereto.

A color filter CF may be disposed on the first planarization film 115.

The color filter CF serves to convert a color of the light emitted from the light-emitting element 120. The color filter CF may be one of a red color filter, a green color filter, and a blue color filter.

In this case, for example, a white color filter may be disposed in the white subpixel, or no color filter may be disposed in the white subpixel.

The color filter CF may be made of a material with a refractive index of about 1.5.

The second planarization film 116 may be disposed above the first planarization film 115 and the color filter CF.

In the display panel DISP of the first embodiment of the present disclosure, the configuration in which the planarization films 115 and 116 are configured as two layers is based on the fact that the number of various types of signal lines increases as the display panel DISP has high resolution. The additional layer is provided because it is difficult to dispose all the lines on a single layer while ensuring minimum intervals. The addition of the additional layer, e.g., the second planarization film 116 may provide a margin for disposing lines, which facilitates the disposition design of lines/electrodes. In addition, in case that a dielectric material is used for the planarization films 115 and 116 having a multilayer structure, the planarization films 115 and 116 may serve to create capacitance between the metal layers.

The second planarization film 116 may be formed such that a part of the connection electrode 135 is exposed. The drain electrode 133 of the thin-film driving transistor 130 and the anode 122 of the light-emitting element 120 may be electrically connected by the connection electrode 135.

The planarization films 115 and 116 may each be made of one or more materials among acrylic resin, epoxy resin, phenolic resin, polyamide resin, polyimide resin, unsaturated polyesters resin, polyphenylene resin, benzocyclobutene resin, and polyphenylene sulfides resin. However, the present disclosure is not limited thereto. For convenience of description, the second planarization film 116 may also be referred to as a planarization film.

According to the first embodiment of the present disclosure, the second planarization film 116 may include a bottom surface layer 116a disposed on the first planarization film 115 and disposed in all the main light-emitting area EA1, a reflection area EA2, the first non-light-emitting area NEA1, and a second non-light-emitting area NEA2, and a protruding portion 116b disposed on the bottom surface layer 116a and protruding at a position corresponding to the main light-emitting area EA1 of the subpixel.

According to the first embodiment of the present disclosure, the second planarization film 116 may have the protruding portion 116b and planarize a top surface of the protruding portion 116b of the second planarization film 116 and a top surface of a bank 117. The top surface of the protruding portion 116b of the second planarization film 116 may correspond to the first area 122a and a second area 122b of the anode 122.

With reference to FIG. 3, in a plan view, the main light-emitting area EA1 or the protruding area PA may have an approximately (or entirely) polygonal shape such as a rectangular shape. However, the present disclosure is not limited thereto. The main light-emitting area EA1 or the protruding area PA may have various shapes such as a circular shape or an elliptical shape.

For example, the protruding portion 116b may include a top surface, a lateral portion, and a bottom surface.

The top surface of the protruding portion 116b may be a surface positioned at an uppermost portion of the second planarization film 116, i.e., a surface substantially parallel to the substrate 111. The top surface of the protruding portion 116b may correspond to the main light-emitting area EA1. In substantially the same way as the main light-emitting area EA1, the top surface of the protruding portion 116b may have an approximately (or entirely) polygonal shape such as a rectangular shape in a plan view. However, the present disclosure is not limited thereto. The top surface of the protruding portion 116b may have various shapes such as a circular shape or an elliptical shape.

The lateral portion of the protruding portion 116b may be a surface extending from the top surface to the side surface of the protruding portion 116b. For example, the lateral portion of the protruding portion 116b may be tapered at a predetermined angle. FIGS. 4 and 5 illustrate an example in which the top surface and the lateral portion of the protruding portion 116b have straight shapes, and a portion where the top surface and the lateral portion of the protruding portion 116b meet together defines a vertex. However, the present disclosure is not limited thereto. The lateral portion of the protruding portion 116b may have a gradual curved line.

In addition, the bottom surface of the protruding portion 116b may be a surface that meets the bottom surface layer 116a, and the bottom surface of the protruding portion 116b may be a surface substantially parallel to the substrate 111. The bottom surface of the protruding portion 116b may correspond to the protruding area PA. In substantially the same way as the protruding area PA, the bottom surface of the protruding portion 116b may have an approximately (or entirely) polygonal shape such as a rectangular shape in a plan view. However, the present disclosure is not limited thereto. The bottom surface of the protruding portion 116b may have various shapes such as a circular shape or an elliptical shape.

The bottom surface layer 116a and the protruding portion 116b of the second planarization film 116 may be made of the same material and integrated. However, the present disclosure is not limited thereto. The bottom surface layer 116a and the protruding portion 116b may be made of different materials and formed by different processes.

For example, the protruding portion 116b may have a height of about 1.0 μm to 1.5 μm. However, the present disclosure is not limited thereto.

For example, the lateral portion of the protruding portion 116b may be tapered at about 45 degrees to form a side mirror structure of a cathode 126. However, the present disclosure is not limited thereto.

For example, the anode 122 may be disposed on a part of the top surface of the bottom surface layer 116a of the second planarization film 116 and the top surface and the lateral portion of the protruding portion 116b. In addition, for example, the anode 122 disposed in the main light-emitting area EA1 may adjoin the top surface of the protruding portion 116b of the second planarization film 116.

The anode 122 may be disposed to correspond to each of the plurality of subpixels. That is, the anodes 122 may be disposed to be divided for the plurality of subpixels. The anode 122 may be made of a transparent conductive material such as indium-tin-oxide (ITO) or indium-zinc-oxide (IZO) so that the light emitted from the light-emitting element 120 exits to the outside through the substrate 111 disposed on a rear surface. In addition, the anode 122 may be a constituent element for supplying positive holes to an organic layer 124 and made of a material with a high work function. The anode 122 may have a single-layer structure or a multilayer structure. The multilayer structure may adjust the light distribution by using a difference in refractive index when materials with different refractive indexes are used. For example, in the multilayer structure, a lower layer may have a higher refractive index than an upper layer.

The anode 122 may include the first area 122a disposed on a part of the top surface of the protruding portion 116b of the second planarization film 116 and having a surface substantially parallel to the surface of the substrate 111, and the second area 122b disposed on another part of the top surface of the protruding portion 116b and having a surface substantially parallel to the surface of the substrate 111.

The second area 122b may be a partial left or right area of the anode 122 disposed on the top surface of the protruding portion 116b, and the first area 122a may be an area excluding the partial left or right area of the anode 122 disposed on the top surface of the protruding portion 116b. For example, the second area 122b may be a part of a left or right edge of the anode 122.

In the first embodiment of the present disclosure, the first area 122a and the second area 122b are different in thickness from each other to widen a light emission distribution of extracted light. The first area 122a may have a larger thickness than the second area 122b. For example, in case that a height of the protruding portion 116b of the second planarization film 116 is 1.0 μm, a length of the second area 122b may be at least 0.732 μm in order to reflect all the light beams having an incident angle of 60 degrees. Therefore, the light beams in an optical path, which does not collide with the side mirror structure of the cathode 126, may be extracted by being reflected by the side mirror structure of the cathode 126.

In addition, the anode 122 may include a third area 122c extending from the first area 122a to the top surface of the bottom surface layer 116a of the second planarization film 116. For example, in a plan view, the third area 122c may be disposed at a lower edge of the main light-emitting area EA1. However, the present disclosure is not limited thereto.

For example, the third area 122c may have substantially the same thickness as the first area 122a and have a larger thickness than the second area 122b. However, the present disclosure is not limited thereto.

For example, the third area 122c of the anode 122 may be spaced apart from the adjacent third area 122c at a predetermined distance in order to suppress a short circuit between the adjacent subpixels.

As described above, in one subpixel, the second planarization film 116 may include at least one contact hole spaced apart from the protruding area PA. The drain electrode 133 of the thin-film driving transistor 130 and the third area 122c of the anode 122 may be electrically connected through the contact hole.

The bank 117 may be disposed on the second planarization film 116.

For example, the bank 117 may be provided on the second planarization film 116 and disposed in the first non-light-emitting area NEA1 of the substrate 111.

The bank 117 may be made of an organic material.

For example, the bank 117 may be made of polyimide-based resin, acryl-based resin, or benzocyclobutene-based resin. However, the present disclosure is not limited thereto.

In addition, the bank 117 may be made of a black material. For example, the bank 117 may be configured by dispersing black dye in an organic material. However, the present disclosure is not limited thereto. The bank 117 may be made of any black material as long as the black material has a black color.

A portion of the bank 117, which corresponds to the main light-emitting area EA1 of the subpixel, may be opened. That is, the bank 117 may be disposed outside the main light-emitting area EA1.

In addition, in the plan view, the portions of the bank 117 of the first embodiment of the present disclosure are differently disposed at the left side, the right side, the upper side, and the lower side of the main light-emitting area EA1. However, the present disclosure is not limited thereto. For example, at the left and right sides of the main light-emitting area EA1, the portions of the bank 117, which correspond to the main light-emitting area EA1, the second non-light-emitting area NEA1, and the reflection area EA2, may be opened. Therefore, at the left and right sides of the main light-emitting area EA1, the bank 117 may be spaced apart from the protruding portion 116b at a predetermined distance. In contrast, at the upper and lower sides of the main light-emitting area EA1, only the portion of the bank 117, which corresponds to the main light-emitting area EA1, may be opened. Therefore, at the upper and lower sides of the main light-emitting area EA1, the bank 117 may adjoin the protruding portion 116b or be disposed adjacent to the protruding portion 116b with the third area 122c interposed therebetween.

Meanwhile, the main light-emitting area EA1 may have a shape corresponding to a shape of the top surface of the protruding portion 116b. The configuration in which a shape of any one constituent element corresponds to a shape of another constituent element may refer to a configuration in which any one constituent element has the same shape as another constituent element, any one constituent element is identical in shape to but different in size from another constituent element, or a shape of any one constituent element and a shape of another constituent element are formed by being transferred by any method. Therefore, the shape of the main light-emitting area EA1 may be understood as being substantially formed by transferring the shape of the top surface of the protruding portion 116b by the light emitted from the organic layer 124 positioned on the top surface of the protruding portion 116b.

In addition, the reflection area EA2 may be positioned to surround the main light-emitting area EA1 without overlapping the main light-emitting area EA1.

In addition, the reflection area EA2 may be a closed curve that surrounds the main light-emitting area EA1. Alternatively, the reflection area EA2 may have a shape made by disconnecting a part of the closed curve.

The subpixels may be distinguished by the main light-emitting area EA1.

The bank 117 may have the lateral portion at the left and right sides of the main light-emitting area EA1, and the lateral portion of the bank 117 may be a surface extending from the top surface to the side surface. The lateral portion of the bank 117 may be tapered at a predetermined angle. For example, the lateral portion of the bank 117 may be tapered at an angle of 30° to 65°. However, the present disclosure is not limited thereto.

In addition, the light-emitting element 120 may be disposed above the second planarization film 116 and electrically connected to the connection electrode 135 through a contact hole.

In this case, for example, the light-emitting element 120 may include the anode 122 connected to the drain electrode 133 of the thin-film driving transistor 130, the plurality of organic layers 124 disposed on the anode 122, and the cathode 126 disposed on the organic layers 124. The organic layer 124 may be referred to as a light-emitting part. However, the present disclosure is not limited to this term.

As described above, the anode 122 may be made of a transparent conductive material.

For convenience of description, FIGS. 4 and 5 illustrate an example in which the anode 122 is configured as a single layer. However, the present disclosure is not limited thereto. The anode 122 may be configured as a multilayer structure.

The organic layer 124 may be disposed above the anode 122.

For example, the organic layer 124 may include a hole injection layer, a hole transport layer, a light-emitting layer, an electron transport layer, and an electron injection layer. In a tandem structure in which a plurality of light-emitting layers overlap, a charge generating layer may be additionally disposed between the light-emitting layers. For example, a common light-emitting layer may be formed to emit white light without distinguishing colors for each of the subpixels, and the color filters CF for distinguishing colors may be separately provided. In this case, the light-emitting layers may be disposed individually. The hole injection layer, the electron injection layer, the hole transport layer, or the electron transport layer may be provided as a common layer and equally disposed for each subpixel.

Meanwhile, at the left and right sides of the main light-emitting area EA1, the organic layer 124 may be disposed on the top surfaces of the first and second areas 122a and 122b of the anode 122, the lateral portion and a part of the top surface of the protruding portion 116b of the second planarization film 116, and the top surface and the lateral portion of the bank 117. At the upper and lower sides of the main light-emitting area EA1, the organic layer 124 may be disposed on the top surface of the first area 122a of the anode 122 and the top surface of the bank 117. However, the present disclosure is not limited thereto.

In addition, the cathode 126 may be disposed on the organic layer 124 so as to be opposite to the anode 122 with the organic layer 124 interposed therebetween.

The cathode 126 may be configured as a common layer without being divided for each of the plurality of subpixels.

The cathode 126 may be made of a metallic material with a low work function in order to supply electrons to the organic layer 124. The cathode 126 may be made of a metallic material with high reflectance in order to reflect the light, which is emitted from the organic layer 124, in a direction toward the substrate 111. For example, the cathode 126 may be made of gold (Au), silver (Ag), aluminum (Al), molybdenum (Mo), magnesium (Mg), or the like or made of an alloy thereof. However, the present disclosure is not limited thereto.

For example, the cathode 126 of the first embodiment of the present disclosure may include a first area 126a disposed in the main light-emitting area EA1 and having a surface substantially parallel to the surface of the substrate 111, and a second area 126b extending from the first area 126a and having a surface having a predetermined angle with respect to the substrate 111. In addition, for example, the second area 126b of the cathode 126 may correspond to the lateral portion of the protruding portion 116b. Therefore, the second area 126b of the cathode 126 may be referred to as a lateral portion of the cathode 126.

The second area 126b of the cathode 126 may be disposed at the left or right side of the main light-emitting area EA1.

In addition, the cathode 126 may further include a third area 126c extending from the second area 126b in a direction toward the adjacent subpixel.

For example, the third area 126c may be disposed above the bank 117.

For example, the third area 126c may be substantially parallel to the surface of the substrate 111. However, the present disclosure is not limited thereto.

In the first embodiment of the present disclosure, the second area 126b of the cathode 126 may have a side mirror shape and constitute a side mirror (SM) structure. The SM structure of the cathode 126 may be configured in the protruding area PA. For example, the SM structure of the cathode 126 may form the reflection area EA2. For example, the reflection area EA2 may have a shape formed along an outline of the main light-emitting area EA1. The reflection area EA2 may have a frame shape having no interruption or a frame shape having interruption. The frame shape having interruption may be a shape that surrounds the outline of the main light-emitting area EA1 and has interruption at the middle thereof.

The second area 126b of the cathode 126 of the first embodiment of the present disclosure may be disposed on the lateral portion of the protruding portion 116b along the shape of the lateral portion of the protruding portion 116b. In this case, the second area 126b of the cathode 126 disposed on the lateral portion of the protruding portion 116b may be tapered at an angle of about 30 to 60 degrees. However, the present disclosure is not limited thereto. The second area 126b of the cathode 126 made of a metallic material with high reflectance may serve as the side mirror (SM). Therefore, the light-emitting area according to the first embodiment of the present disclosure may further include the reflection area EA2 provided by the SM structure in addition to the main light-emitting area EA1. For example, the reflection area EA2 may be formed between the main light-emitting area EA1 corresponding to the first area 122a and the second area 122b of the anode 122 and the first non-light-emitting area NEA1. Meanwhile, the second non-light-emitting area NEA2 may be formed between the reflection area EA2 and the main light-emitting area EA1.

In the first embodiment of the present disclosure, the SM structure configured in the protruding area PA forms the reflection area EA2. A part of the light emitted from the light-emitting element 120 is reflected by the SM structure from the second area 126b of the cathode 126 and form the reflection area EA2 having the frame shape (see dotted arrows in FIG. 5). Therefore, the light extraction efficiency may be improved.

As described above, the light extraction efficiency is improved by the side mirror structure, i.e., the second area 126b of the cathode 126. Specifically, it is possible to extract light trapped in a substrate mode and a waveguide mode by means of the second area 126b of the cathode 126. However, because light cannot be extracted in the case of an optical path having a light emission distribution angle smaller than an angle (θ in FIG. 5) of the second area 126b of the cathode 126, the second area 126 b of the cathode 126 is tapered at an angle of at most 45 degrees. As described above, the light having an angle equal to or smaller than the maximum taper angle of the second area 126b of the cathode 126 cannot be extracted. In particular, because the blue light has a higher absorption rate than the red or green light, the light extraction efficiency may be further decreased.

Therefore, in the first embodiment of the present disclosure, the areas 122a and 122b are different in thickness of the anode 122, such that the light emission distribution of the extracted light may be increased. It can be seen that the light emission distribution of the extracted light is further widened as the thickness of the second area 122b of the edge of the anode 122 decreases (see arrows \textcircled{1} and \textcircled{2} in FIG. 5). Therefore, the light in the optical path, which does not collide with the second area 126b of the cathode 126 in the related art, may be extracted by being reflected by the second area 126b. The blue light will be described as an example with reference to FIG. 5. It can be seen that blue light beams (arrow \textcircled{2}) emitted from the second area 126b of the anode 122 having a relatively small thickness form wider light emission distribution than blue light beams (arrow \textcircled{1}) emitted from the first area 122a of the anode 122 having a relatively large thickness. Therefore, the luminance may be improved. In this case, as the luminance is improved, power consumption may be reduced, the amount of use of fossil fuel for producing power may be reduced by the low power consumption, and the emission of greenhouse gases may be reduced, such that ESG (Environment/Social/Governance) may be implemented.

A micro-cavity is designed to emit the largest amount of forward light emission when the light-emitting element 120 is formed. In case that the design of the micro-cavity is changed, the light beams, which propagate forward in accordance with the design in the related art, are spread laterally, such that the amount of lateral light emission may be relatively larger than the amount of forward light emission. Therefore, when the thickness of the second area 122b of the edge of the anode 122 decreases on the basis of the above-mentioned configuration, the cavity may be changed, and the light emission distribution may be widened. A path of light may be changed by refraction, reflection, and the like while the light passes through several layers until the light is emitted in the light-emitting element 120 and exits to the outside. Therefore, in the case of the light-emitting element 120, it is possible to design the micro-cavity so that the largest amount of forward light emission is implemented when the amount of light emission remains the same. In this regard, in case that the thickness of the anode 122 decreases in the corresponding design, the amount of forward light emission is relatively decreased by the changed micro-cavity, and the amount of lateral light emission is increased. Therefore, the thickness of the second area 122b of the edge of the anode 122 in the design in the related art is decreased, the light emission distribution may be widened, and the side mirror structure of the cathode 126 may be more properly used.

For reference, the electroluminescence spectrum is configured as a sum of a luminescence spectrum and a photoluminescence spectrum. The luminescence spectrum refers to the amount of light emitted with various wavelengths from a particular material or device.

In addition, the photoluminescence spectrum refers to a spectrum of light emitted by a material after the material absorbs light (generally, UV rays or visible rays). The electroluminescence spectrum refers to a spectrum of light emitted when the electroluminescent display device receives a current.

Analysis of the electroluminescence spectrum shows that the luminescence spectrum varies depending on the wavelength at a viewing angle, i.e., an incident angle of 45 and 60 degrees in comparison with the forward spectrum with an incident angle of 0 degrees.

Therefore, it can be seen that the light emission distribution may be widened by various viewing angles.

An encapsulation layer may be positioned above the light-emitting element 120.

In this case, the encapsulation layer may have a single layer structure or a multilayer structure. For example, the encapsulation layer may include a first encapsulation layer, a second encapsulation layer, and a third encapsulation layer.

For example, the first encapsulation layer and the third encapsulation layer may each be made of an inorganic film, and the second encapsulation layer may be made of an organic film. For example, among the first encapsulation layer, the second encapsulation layer, and the third encapsulation layer, the second encapsulation layer may be thickest and serve as a planarization film.

The first encapsulation layer may be made of an inorganic insulating material that may be subjected to low-temperature deposition. For example, the first encapsulation layer may be made of silicon nitride (SiNx), silicon oxide (SiOx), silicon oxynitride (SiON), aluminum oxide (Al₂O₃), or the like.

The second encapsulation layer may have a smaller area than the first encapsulation layer. In this case, the second encapsulation layer may be formed to expose two opposite ends of the first encapsulation layer.

In addition, for example, the second encapsulation layer may be made of an organic insulating material such as acrylic resin, epoxy resin, polyimide, polyethylene, or silicon oxycarbon (SiOC). In addition, for example, the second encapsulation layer may also be formed in an inkjet manner. However, the present disclosure is not limited thereto.

The third encapsulation layer may be formed to cover top surfaces and side surfaces of first and second encapsulation layers.

For example, the third encapsulation layer may minimize or block the permeation of outside moisture or oxygen into the first encapsulation layer and the second encapsulation layer. In addition, for example, the third encapsulation layer may be made of an inorganic insulating material such as silicon oxide (SiOx), silicon oxynitride (SiON), aluminum oxide (Al₂O₃), or silicon nitride (SiNx).

Meanwhile, in the first embodiment of the present disclosure, in case that a height of the protruding portion of the second planarization film is 1.0 μm, a length of the second area of the anode may be at least 0.732 μm in order to reflect all the light beams with an incident angle of 60 degrees. This configuration will be described below in detail.

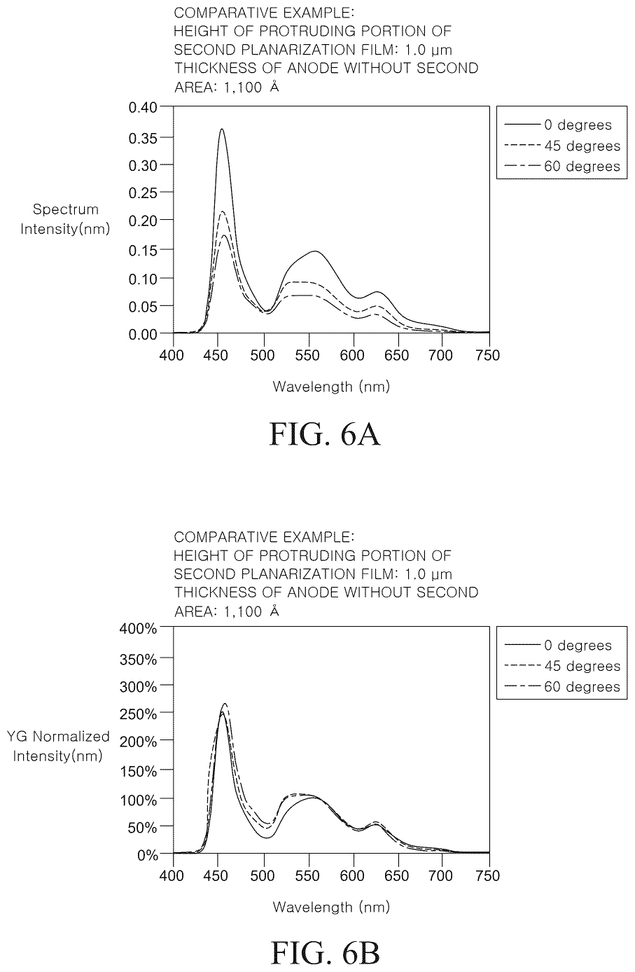

FIGS. 6A and 6B are graphs illustrating electroluminescence spectra of a comparative example.

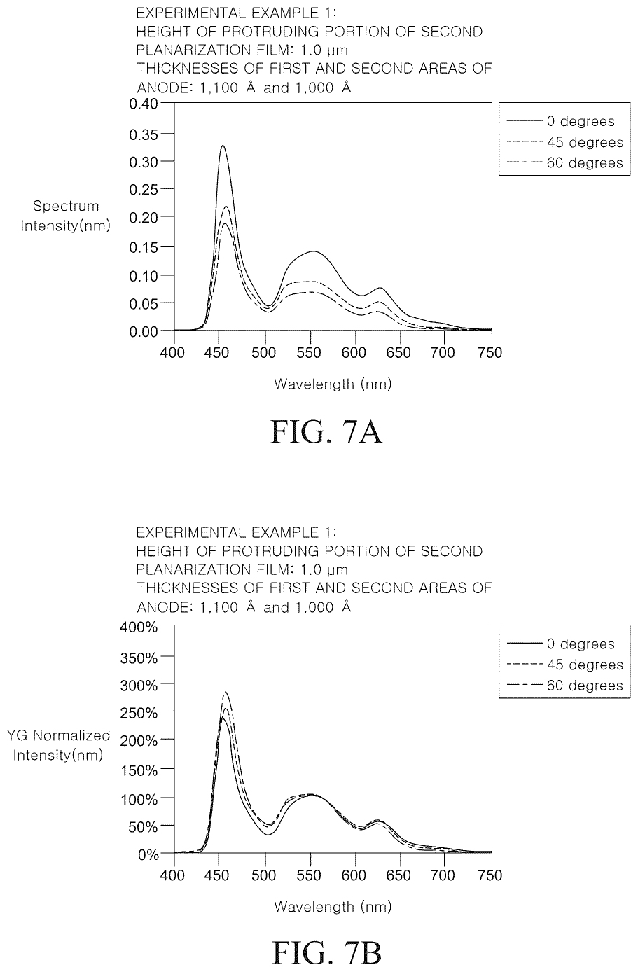

FIGS. 7A and 7B are graphs illustrating electroluminescence spectra of Experimental Example 1.

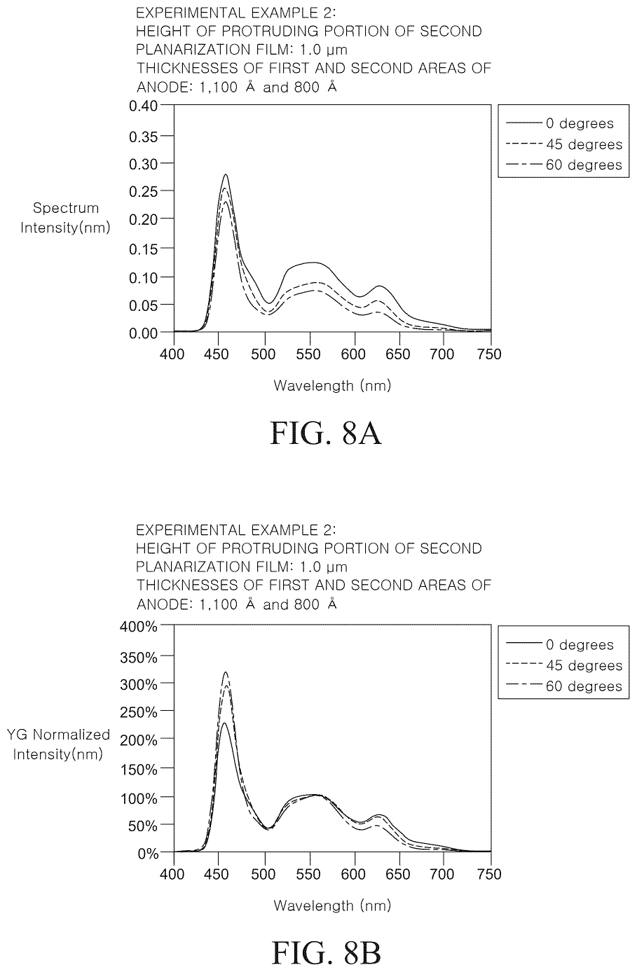

FIGS. 8A and 8B are graphs illustrating electroluminescence spectra of Experimental Example 2.

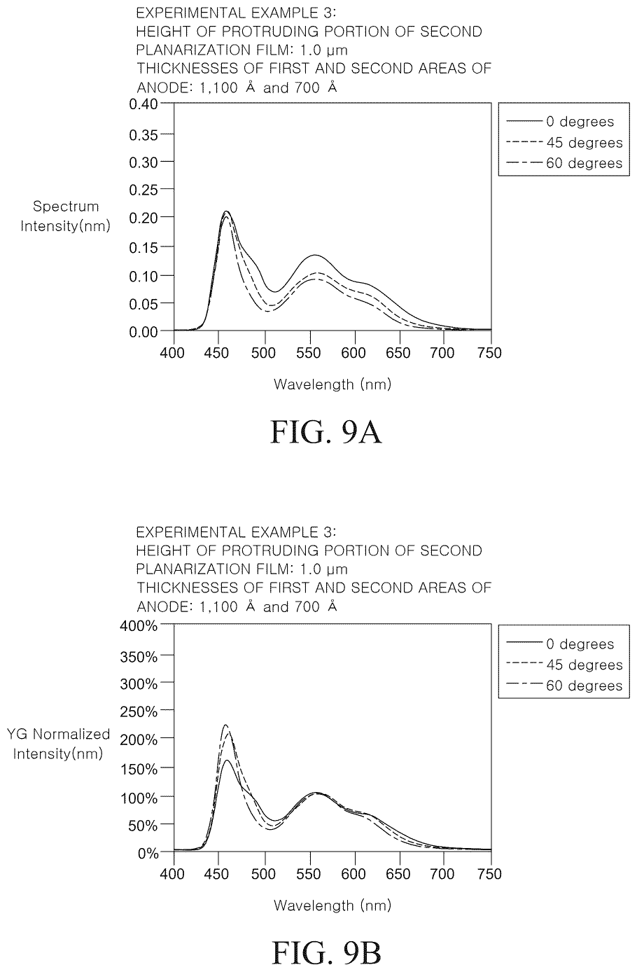

FIGS. 9A and 9B are graphs illustrating electroluminescence spectra of Experimental Example 3.

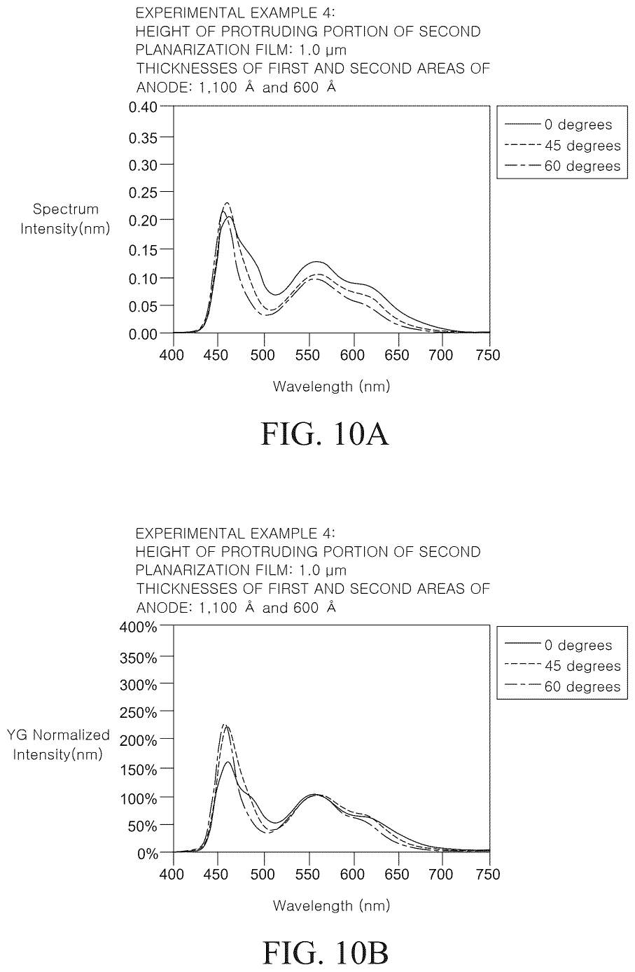

FIGS. 10A and 10B are graphs illustrating electroluminescence spectra of Experimental Example 4.

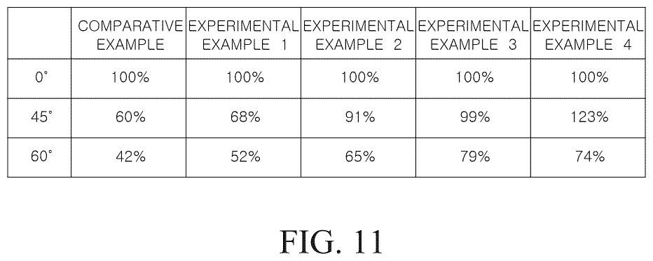

FIG. 11 is a table showing intensities of electroluminescence spectra with respect to incident angles of the comparative example and Experimental Examples 1 to 4.

From the results illustrated in FIG. 6A, 6B to 10A, and 10B, it is possible to derive the height of the protruding portion of the second planarization film that may maximally improve the efficiency and luminance by allowing the side mirror structure of the cathode to reflect a larger amount of light.

FIGS. 6A and 6B are graphs illustrating electroluminescence spectra of the comparative example when the height of the protruding portion of the second planarization film is 1.0 μm and the thickness of the anode is 1,100 Å without the second area.

FIGS. 7A, 7B to 10A, and 10B are graphs illustrating electroluminescence spectra of Experimental Examples 1 to 4 in which the height of the protruding portion of the second planarization film is 1.0 μm and the first and second areas are different in thickness of the anode. In Experimental Examples 1 to 4 in FIGS. 7A, 7B to 10A, and 10B, the thickness of the first area is constant as 1,100 Å, and the thickness of the second area may be smaller than the thickness of the first area. In addition, in Experimental Examples 1 to 4, the length of the second area may be 0.732 μm.

In FIGS. 7A, 7B to 10A, and 10B, the protruding portion of the second planarization film may be tapered at 45 degrees, the refractive index of the second planarization film may be about 1.57, and the refractive index of the organic layer may be about 1.9 to 2.1.

FIGS. 7A and 7B are graphs illustrating electroluminescence spectra of Experimental Example 1 when the thickness of the second area of the anode is 1,000 Å.

FIGS. 8A and 8B are graphs illustrating electroluminescence spectra of Experimental Example 2 when the thickness of the second area of the anode is 800 Å.

FIGS. 9A and 9B are graphs illustrating electroluminescence spectra of Experimental Example 3 when the thickness of the second area of the anode is 700 Å.

FIGS. 10A and 10B are graphs illustrating electroluminescence spectra of Experimental Example 4 when the thickness of the second area of the anode is 600 Å.

FIGS. 7A, 8A, 9A, and 10A are graphs illustrating electroluminescence spectra with respect to wavelengths at incident angles of 0 degrees, 45 degrees, and 60 degrees.

In addition, FIGS. 7B, 8B, 9B, and 10B are graphs illustrating electroluminescence spectra made by normalizing the graphs of the electroluminescence spectra in FIGS. 7A, 8A, 9A, and 10A with an intensity of light in a YG area (556 nm) as 100%.

It can be seen that in the case of the comparative example in FIGS. 6A and 6B, the intensities of the electroluminescence spectra have values of 100%, 60%, and 42% at the incident angles of 0 degrees, 45 degrees, and 60 degrees. That is, it can be seen that the intensity of the electroluminescence spectrum decreases as the incident angle increases to 45 degrees and 60 degrees in comparison with the incident angle of 0 degrees. In this case, the intensity of the electroluminescence spectrum may refer to a relative value when the incident angle of 0 degrees is 100%.

It can be seen that in the case of Experimental Example 1 in FIGS. 7A and 7B, the intensities of the electroluminescence spectra have values of 100%, 68%, and 52% at the incident angles of 0 degrees, 45 degrees, and 60 degrees. It can be seen that a degree to which the intensity of the electroluminescence spectrum decreases is reduced in both the cases in which the incident angles are 45 degrees and 60 degrees in comparison with the comparative example.

It can be seen that in the case of Experimental Example 2 in FIGS. 8A and 8B, the intensities of the electroluminescence spectra have values of 100%, 91%, and 65% at the incident angles of 0 degrees, 45 degrees, and 60 degrees. It can be seen that the degree to which the intensity of the electroluminescence spectrum decreases is further reduced in both the cases in which the incident angles are 45 degrees and 60 degrees in comparison with the comparative example. It can be seen that in the case of Experimental Example 2, the intensity of the electroluminescence spectrum is maintained to be 90% or more when the incident angle is 45 degrees.

In addition, it can be seen that in the case of Experimental Example 3 in FIGS. 9A and 9B, the intensities of the electroluminescence spectra have values of 100%, 99%, and 79% at the incident angles of 0 degrees, 45 degrees, and 60 degrees. It can be seen that the degree to which the intensity of the electroluminescence spectrum decreases is further reduced in both the cases in which the incident angles are 45 degrees and 60 degrees in comparison with the comparative example. It can be seen that in the case of Experimental Example 3, the intensity of the electroluminescence spectrum is maintained to be 98% or more when the incident angle is 45 degrees, and the intensity of the electroluminescence spectrum is approximate to 80% even when the incident angle is 60 degrees.

In addition, it can be seen that in the case of Experimental Example 4 in FIGS. 10A and 10B, the intensities of the electroluminescence spectra have values of 100%, 123%, and 74% at the incident angles of 0 degrees, 45 degrees, and 60 degrees. It can be seen that the intensity of the electroluminescence spectrum increases in both the cases in which the incident angles are 45 degrees and 60 degrees in comparison with the comparative example. However, it can be seen that in the case of Experimental Example 4, the intensity of the electroluminescence spectrum decreases to 74% when the incident angle is 60 degrees in comparison with Experimental Example 3. Therefore, it can be seen that Experimental Example 3 has the optimal result capable of maximally improving the efficiency and luminance.

The change in light emission distribution may be identified on the basis of the intensities of the electroluminescence spectra corresponding to the viewing angles of 0 to 60 degrees from the results in FIGS. 6A, 6B to 10A, 10B, and 11. In particular, it can be ascertained that the light emission distribution increases when the intensity of the electroluminescence spectrum corresponding to the viewing angle of 60 degrees increases.

It can be seen that in the case of the comparative example in FIGS. 6A and 6B, the intensity of the electroluminescence spectrum corresponding to the viewing angle of 60 degrees is 42% in comparison with the front view. In addition, it can be seen that in the case of Experimental Example 1 in FIGS. 7A and 7B, the intensity of the electroluminescence spectrum corresponding to the viewing angle of 60 degrees is 52% in comparison with the front view. In addition, it can be seen that in the case of Experimental Example 2 in FIGS. 8A and 8B, the intensity of the electroluminescence spectrum corresponding to the viewing angle of 60 degrees is 65% in comparison with the front view.

In addition, it can be seen that in the case of Experimental Example 3 in FIGS. 9A and 9B, the intensity of the electroluminescence spectrum corresponding to the viewing angle of 60 degrees is 79% in comparison with the front view. In addition, it can be seen that in the case of Experimental Example 4 in FIGS. 10A and 10B, the intensity of the electroluminescence spectrum corresponding to the viewing angle of 60 degrees is 74% in comparison with the front view.

As described above, it can be seen that at the viewing angle of 60 degrees, the intensity of the electroluminescence spectrum increases to 79% in Experimental Example 3 in comparison with 42% in the comparative example. Further, it can be seen that the light emission distribution of the light beams of about 37% increases to 60 degrees or more. As described above, the light beams with the increased light emission distribution additionally utilizes the side mirror structure of the cathode, which contributes to additional light emission.

As described above, it can be seen that the degree to which the intensity of the electroluminescence spectrum decreases is reduced as the thickness of the second area of the anode becomes smaller than that of the first area, but a reversal phenomenon occurs in case that the thickness of the second area decreases from 700 Å to 600 Å when the thickness of the first area is 1,100 Å. Therefore, in the present disclosure, the thickness of the second area may have a value of 700 Å to 1,000 Å when the thickness of the first area of the anode is 1,100 Å. For example, in the present disclosure, the thickness of the second area of the anode may have a value of 64% to 91% of the thickness of the first area.

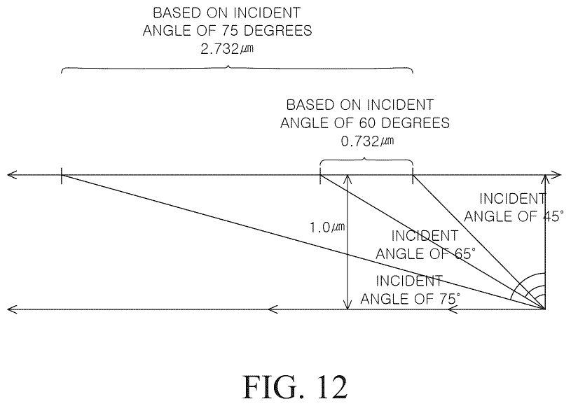

FIG. 12 is a view illustrating a simulation result showing light emission in accordance with light emission incident angles.

FIG. 12 illustrates directionality of the light beams having an incident angle of 60 degrees based on the light beams having an incident angle of 60 degrees among the light beams emitted in a downward direction. The light beams having the directionality may propagate in parallel with one direction in the two layer.

With reference to FIG. 12, in case that the protruding portion of the second planarization film is tapered at 45 degrees and the height of the protruding portion is 1.0 μm, all the light beams having an incident angle of 60 degrees or less may be reflected by the side mirror structure of the cathode. Therefore, in this case, the length of the second area of the anode may have a value of at most 0.732 μm. If all the light beams having an incident angle of 75 degrees or less are utilized for the side mirror structure of the cathode, the length of the second area of the anode may have a value of at least 2.732 μm.

In case that the height of the protruding portion is 1.5 μm when the same simulation is applied, the length of the second area of the anode may have a value of at least 2.674 μm in order to utilize all the light beams, which have an incident angle of 60 degrees or less, for the side mirror structure of the cathode. If all the light beams having an incident angle of 75 degrees or less are utilized for the side mirror structure of the cathode, the length of the second area of the anode may have a value of at least 4.590 μm.

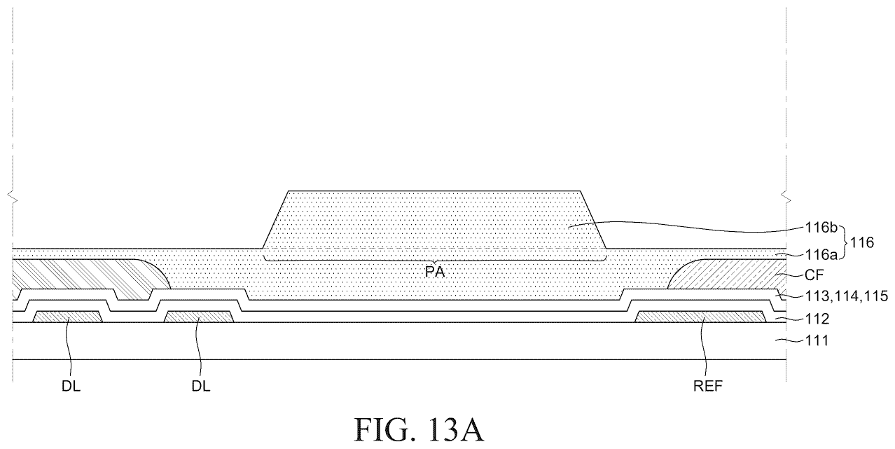

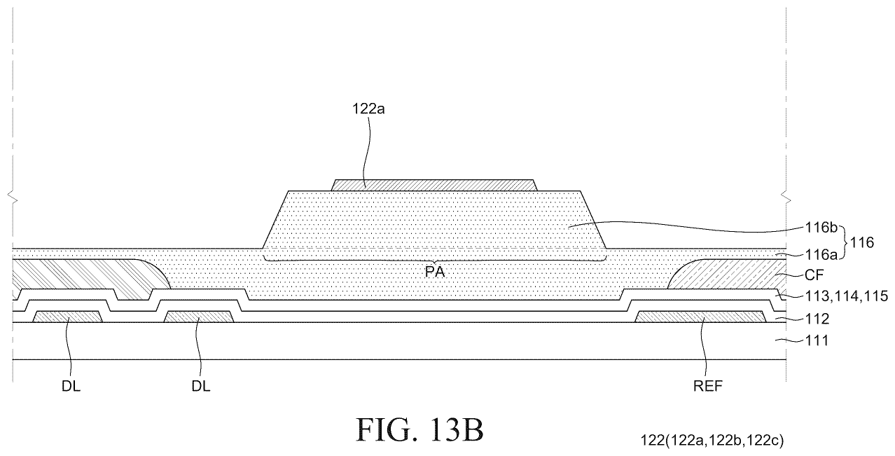

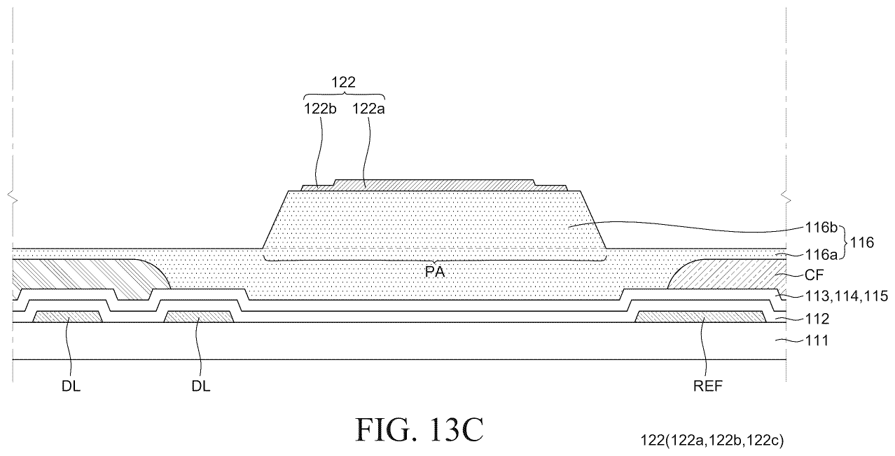

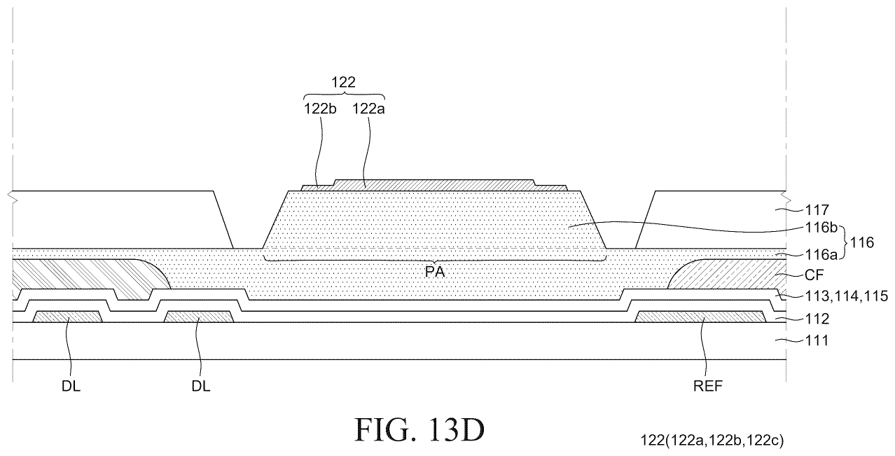

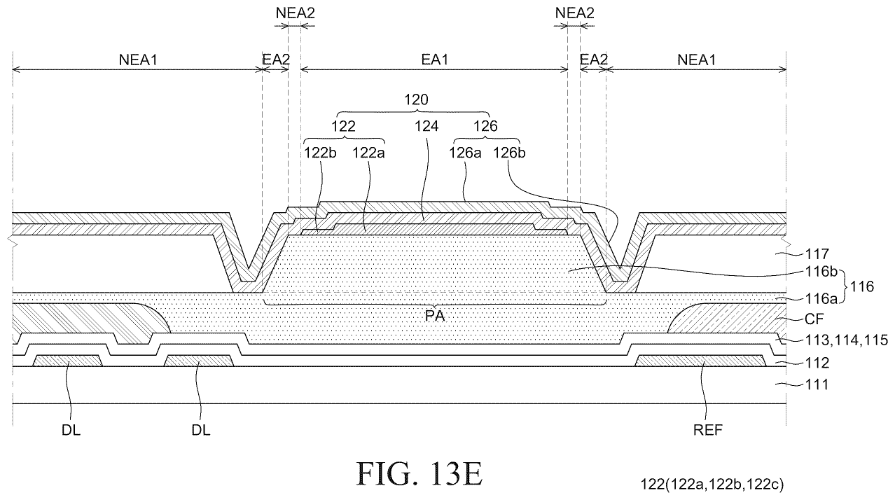

FIGS. 13A to 13E are cross-sectional views sequentially illustrating a part of a process of manufacturing the display panel in FIG. 5.

With reference to FIG. 13A, the buffer layer 112, such as a multi-buffer layer or a lower buffer layer, may be formed above the substrate 111.

Various signal lines, such as the data line DL, the reference voltage line REF, or the common voltage line, may be formed on the substrate 111.

The thin-film driving transistor 130 may be formed above the buffer layer 112.

The protective film may be formed above the thin-film driving transistor 130. The protective film may be excluded in some instances.

The planarization films 115 and 116 may be formed on the protective film.

The planarization films 115 and 116 may have a multilayer structure including at least two layers. For example, the planarization films 115 and 116 may include the first planarization film 115 and the second planarization film 116. However, the present disclosure is not limited thereto.

For example, the connection electrode 135 may be formed on the first planarization film 115 and electrically connect the thin-film driving transistor 130 and the light-emitting element 120.

The color filter CF may be formed on the first planarization film 115.

The second planarization film 116 may be formed above the first planarization film 115 and the color filter CF.

In this case, the second planarization film 116 may include the bottom surface layer 116a disposed on the entire substrate 111, and the protruding portion 116b disposed on the bottom surface layer 116a and protruding at a positioncorresponding to the main light-emitting area EA1 of the subpixel.

For example, the protruding portion 116b may include the top surface, the lateral portion, and the bottom surface.

The bottom surface layer 116a and the protruding portion 116b of the second planarization film 116 may be made of the same material and integrated. However, the present disclosure is not limited thereto. The bottom surface layer 116a and the protruding portion 116b may be made of different materials and formed by different processes.

For example, the protruding portion 116 b may have a height of about 1.0 μm to 1.5 μm. However, the present disclosure is not limited thereto.

For example, the lateral portion of the protruding portion 116b may be tapered at about 45 degrees to form the side mirror structure of the cathode 126. However, the present disclosure is not limited thereto.

Thereafter, with reference to FIG. 13B, the first area 122a of the anode 122 may be formed on the protruding portion 116b of the second planarization film 116 by a mask process (photolithography process). In addition, the third area 122c extending from the first area 122a to the top surface of the bottom surface layer 116a of the second planarization film 116 may be formed by the same mask process.

The first area 122a of the anode 122 may be disposed on a part of the top surface of the protruding portion 116b of the second planarization film 116 and have the surface substantially parallel to the surface of the substrate 111.

The third area 122c of the anode 122 may extend from the lower edge of the first area 122a to the lateral portion of the protruding portion 116b and the top surface of the bottom surface layer 116a.

For example, the third area 122c of the anode 122 may be spaced apart from the adjacent third area 122c at a predetermined distance in order to suppress a short circuit between the adjacent subpixels.

In this case, the second planarization film 116 may include at least one contact hole spaced apart from the protruding area PA. The drain electrode 133 of the thin-film driving transistor 130 and the third area 122c of the anode 122 may be electrically connected through the contact hole.

Thereafter, with reference to FIG. 13C, the second area 122b may be formed at the left or right side of the first area 122a by a mask process (photolithography process).

For example, the first area 122a may be formed on a part of the top surface of the protruding portion 116b of the second planarization film 116 by depositing and patterning a conductive film on the entire substrate 111 to cover the first area 122a. Meanwhile, the second area 122b may be formed on another part of the top surface of the protruding portion 116b.

That is, the second area 122b may be disposed on another part of the top surface of the protruding portion 116b and have the surface substantially parallel to the surface of the substrate 111.

The second area 122b may be a partial left or right area of the anode 122 disposed on the top surface of the protruding portion 116b, and the first area 122a may be an area excluding the partial left or right area of the anode 122 disposed on the top surface of the protruding portion 116b. For example, the second area 122b may be a part of the left or right edge of the anode 122.

Therefore, the first area 122a and the second area 122b may have different thicknesses. The first area 122a may have a larger thickness than the second area 122b. In addition, the third area 122c may have substantially the same thickness as the first area 122a.

The anode 122, which is formed as described above, may be disposed to correspond to each of the plurality of subpixels. That is, the anodes 122 may be disposed to be divided for the plurality of subpixels. The anode 122 may be made of a transparent conductive material such as indium-tin-oxide (ITO) or indium-zinc-oxide (IZO). The anode 122 may have a single-layer structure or a multilayer structure. The multilayer structure may adjust the light distribution by using a difference in refractive index when materials with different refractive indexes are used. For example, in the multilayer structure, a lower layer may have a higher refractive index than an upper layer.

Thereafter, with reference to FIG. 13D, the bank 117 may be formed on the second planarization film 116.

A portion of the bank 117, which corresponds to the main light-emitting area EA1 of the subpixel, may be opened. That is, the bank 117 may be formed outside the main light-emitting area EA1.

In addition, the portions of the bank 117 of the first embodiment of the present disclosure are differently disposed at the left side, the right side, the upper side, and the lower side of the main light-emitting area EA1. However, the present disclosure is not limited thereto. For example, at the left and right sides of the main light-emitting area EA1, the portions of the bank 117, which correspond to the main light-emitting area EA1, the second non-light-emitting area NEA1, and the reflection area EA2, may be opened. Therefore, at the left and right sides of the main light-emitting area EA1, the bank 117 may be spaced apart from the protruding portion 116b at a predetermined distance. In contrast, at the upper and lower sides of the main light-emitting area EA1, only the portion of the bank 117, which corresponds to the main light-emitting area EA1, may be opened. Therefore, at the upper and lower sides of the main light-emitting area EA1, the bank 117 may adjoin the protruding portion 116b or be disposed adjacent to the protruding portion 116b with the third area 122c interposed therebetween (see FIG. 4 together).

Thereafter, with reference to FIG. 13E, the light-emitting element 120 may be formed by depositing the organic layer 124 and the cathode 126 on the anode 122.

For example, the cathode 126 of the first embodiment of the present disclosure may include the first area 126a disposed in the main light-emitting area EA1 and having the surface substantially parallel to the surface of the substrate 111, and the second area 126b extending from the first area 126a and having the surface having a predetermined angle with respect to the substrate 111.

The second area 126b of the cathode 126 may be disposed at the left or right side of the main light-emitting area EA1.

Thereafter, although not illustrated, the encapsulation layer may be formed above the light-emitting element 120.

Meanwhile, the anode of the present disclosure may have two areas, i.e., the first and second areas having different thicknesses. However, the present disclosure is not limited thereto. Three areas including a first area, a second-first area, and a second-second area may have different thicknesses. This configuration will be described in detail with reference to the second embodiment of the present disclosure.

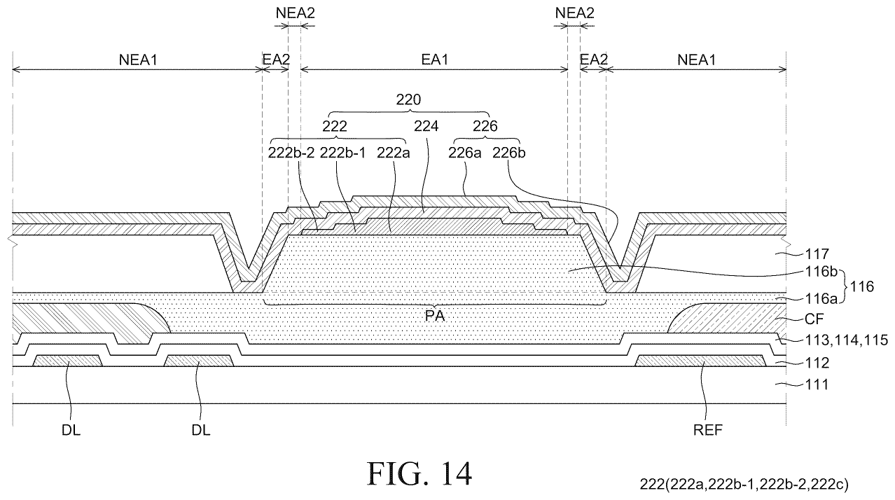

FIG. 14 is a cross-sectional view illustrating a display panel according to a second embodiment of the present disclosure.

The second embodiment of the present disclosure in FIG. 14 is substantially identical in configuration to the above-mentioned first embodiment in FIGS. 3 to 4, except that three areas, i.e., the first area, the second-first area, and the second-second area are different in thickness of the anode. Therefore, repeated descriptions of the identical components will be omitted. The same reference numerals are used for the same components. Hereinafter, the components denoted by the same reference numerals will be described with reference to FIGS. 1 to 4.

With reference to FIG. 14, the first planarization film 115 may be disposed above the substrate 111.

The color filter CF may be disposed on the first planarization film 115.

The second planarization film 116 may be disposed above the first planarization film 115 and the color filter CF.

In this case, the second planarization film 116 may include the bottom surface layer 116a disposed on the entire substrate 111, and the protruding portion 116b disposed on the bottom surface layer 116a and protruding at a positioncorresponding to the main light-emitting area EA1 of the subpixel.

For example, the protruding portion 116b may include the top surface, the lateral portion, and the bottom surface.

The bottom surface layer 116a and the protruding portion 116b of the second planarization film 116 may be made of the same material and integrated. However, the present disclosure is not limited thereto. The bottom surface layer 116a and the protruding portion 116b may be made of different materials and configured by different processes.

For example, the protruding portion 116 b may have a height of about 1.0 μm to 1.5 μm. However, the present disclosure is not limited thereto.

For example, the lateral portion of the protruding portion 116b may be tapered at about 45 degrees to form a side mirror structure of a cathode 226. However, the present disclosure is not limited thereto.

For example, an anode 222 may be disposed on a part of the top surface of the bottom surface layer 116a of the second planarization film 116 and the top surface and the lateral portion of the protruding portion 116b.

The anode 222 may include a first area 222a disposed on a part of the top surface of the protruding portion 116b of the second planarization film 116 and having a surface substantially parallel to the surface of the substrate 111, and a second-first area 222b-1 and a second-second area 222b-2 disposed on another part of the top surface of the protruding portion 116b and having surfaces substantially parallel to the surface of the substrate 111. However, the present disclosure is not limited thereto. A plurality of second areas may be disposed on another part of the top surface of the protruding portion 116b.

The second-first area 222b-1 and the second-second area 222b-2 according to the second embodiment of the present disclosure may be partial left and right areas of the anode 222 disposed on the top surface of the protruding portion 116b, and the first area 222a may be an area excluding the partial left or right area of the anode 222 disposed on the top surface of the protruding portion 116b. The second-first area 222b-1 and the second-second area 222b-2 may be parts of the left and right edges of the anode 222. For example, the second-second area 222b-2 may be positioned outward of the second-first area 222b-1.

In the second embodiment of the present disclosure, the first area 222a, the second-first area 222b-1, and the second-second area 222b-2 may be different in thickness from one another to widen the light emission distribution of the extracted light. The first area 222a may have a larger thickness than the second-first area 222b-1 and the second-second area 222b-2. In addition, the second-first area 222b-1 may have a larger thickness than the second-second area 222b-2. For example, in case that a height of the protruding portion 116b of the second planarization film 116 is 1.0 μm, a total length of the second-first area 222b-1 and the second-second area 222b-2 may be at least 0.732 μm in order to reflect all the light beams having an incident angle of 60 degrees. Therefore, the light beams in an optical path, which does not collide with the side mirror structure of the cathode 226, may be extracted by being reflected by the side mirror structure of the cathode 226.

In addition, the anode 222 may include a third area 222c extending from the first area 222a to the top surface of the bottom surface layer 116a of the second planarization film 116. For example, in a plan view, the third area 222c may be disposed at the lower edge of the main light-emitting area EA1. However, the present disclosure is not limited thereto.

For example, the third area 222c may have substantially the same thickness as the first area 222a, and the second-first area 222b-1 may have a larger thickness than the second-second area 222b-2. However, the present disclosure is not limited thereto.

The bank 117 may be disposed on the second planarization film 116.

An organic layer 224 and the cathode 226 may be disposed on the anode 222.

The anode 222, the organic layer 224, and the cathode 226 may constitute a light-emitting element 220.

For example, the cathode 226 of the second embodiment of the present disclosure may include a first area 226a disposed in the main light-emitting area EA1 and having a surface substantially parallel to the surface of the substrate 111, and a second area 226b extending from the first area 226a and having a surface having a predetermined angle with respect to the substrate 111.

The second area 226b of the cathode 226 may be disposed at the left or right side of the main light-emitting area EA1. In the second embodiment of the present disclosure, the second area 226b of the cathode 226 may have a side mirror shape and constitute a side mirror (SM) structure.

The encapsulation layer may be disposed above the light-emitting element 220.

As described above, in the second embodiment of the present disclosure, the second-first area 222b-1 and the second-second area 222b-2, which have sequentially smaller thicknesses than the first area 222a, are disposed at the left and right edges of the first area 222a of the anode 222, and the thicknesses of the anode 222 are more finely differentiated, such that the light emission distribution may be further widened.

The exemplary embodiments of the present disclosure can also be described as follows:

According to an aspect of the present disclosure, there is provided a display device. The display device includes a planarization film disposed above a substrate and having a protruding portion, an anode disposed on a top surface of the protruding portion of the planarization film and including at least first and second areas having different thicknesses, an organic layer disposed on the anode and a cathode disposed on the organic layer corresponding to the top surface and a lateral portion of the protruding portion.

The planarization film may comprise a bottom surface layer and the protruding portion disposed on the bottom surface layer and protruding to corresponding to a main light-emitting area of a subpixel.

The top surface of the protruding portion may be positioned at an uppermost portion of the planarization film, and the top surface of the protruding portion may have a polygonal shape, a circular shape, or an elliptical shape in a plan view.

The protruding portion may further comprise the lateral portion extending from the top surface to a side surface of the protruding portion, the protruding portion may have a height of 1.0 μm to 1.5 μm, and a length of the second area may be at least 70% of the height of the protruding portion.

The anode may be disposed on a part of a top surface of the bottom surface layer and on the top surface and the lateral portion of the protruding portion.

The first area of the anode may be disposed on a part of the top surface of the protruding portion, and the second area of the anode may be disposed on another part of the top surface of the protruding portion.

The second area may be disposed at a left or right side of the first area.

The first area may have a larger thickness than the second area.

The anode may further comprise a third area extending from the first area to a top surface of the bottom surface layer, and the third area may be disposed at a lower edge of the main light-emitting area in a plan view.

The third area may have the same thickness as the first area.

The display device may further comprise a bank disposed on a part of a top surface of the planarization film excluding the protruding portion.

A part of the bank corresponding to the main light-emitting area, a second non-light-emitting area, and a reflection area, may be open at a left or right side of the main light-emitting area, and only a part of the bankcorresponding to the main light-emitting area, may be open at an upper or lower side of the main light-emitting area.

The reflection area may be positioned so as to surround the main light-emitting area without overlapping with the main light-emitting area.

The organic layer may be disposed on top surfaces of the first and second areas, the lateral portion and a part of the top surface of the protruding portion, and a top surface and a lateral portion of the bank at a left or right side of the main light-emitting area, and the organic layer may be disposed on the top surface of the first area and the top surface of the bank at an upper or lower side of the main light-emitting area.

The cathode may comprise a first area disposed in the main light-emitting area; and a second area extending from the first area of the cathode and corresponding to the lateral portion of the protruding portion.

The second area of the cathode may be disposed at the left or right side of the main light-emitting area and forms the reflection area.

The second area may comprise a second-first area and a second-second area having different thicknesses.

The second-second area may be positioned outward of the second-first area.

The first area may have a larger thickness than the second-first area and the second-second area, and the second-first area may have a larger thickness than the second-second area.

A thickness of the second area of the anode may be 64% to 91% of a thickness of the first area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device comprising:
a planarization film disposed above a substrate and having a protruding portion;
an anode disposed on a top surface of the protruding portion of the planarization film and including at least a first area and a second area having different thicknesses;
an organic layer disposed on the anode corresponding to the top surface and a side surface of the protruding portion; and
a cathode disposed on the organic layer corresponding to the top surface and the side surface of the protruding portion.

2. The display device of claim 1, wherein the planarization film comprises:
a bottom surface layer; and
the protruding portion disposed on the bottom surface layer and protruding to a main light-emitting area of a subpixel.

3. The display device of claim 1, wherein the top surface of the protruding portion is positioned at an uppermost portion of the planarization film, and the top surface of the protruding portion has a polygonal shape, a circular shape, or an elliptical shape in a plan view.

4. The display device of claim 2, wherein the protruding portion further comprises a lateral portion extending from the top surface to the side surface of the protruding portion,
wherein the protruding portion has a height of 1.0 μm to 1.5 μm, and a length of the second area is at least 70% of the height of the protruding portion.

5. The display device of claim 4, wherein the lateral portion of the protruding portion is tapered at a predetermined angle.

6. The display device of claim 2, wherein the anode is disposed on a part of a top surface of the bottom surface layer and on the top surface and the lateral portion of the protruding portion.

7. The display device of claim 2, wherein the first area of the anode is disposed on a part of the top surface of the protruding portion, and the second area of the anode is disposed on another part of the top surface of the protruding portion.

8. The display device of claim 7, wherein the second area of the anode is disposed at a left or right side of the first area of the anode.

9. The display device of claim 8, wherein the first area of the anode has a larger thickness than the second area of the anode.

10. The display device of claim 9, wherein the anode further comprises a third area extending from the first area of the anode to a top surface of the bottom surface layer, wherein the third area of the anode is disposed at a lower edge of the main light-emitting area in a plan view, and wherein the third area of the anode has a same thickness as the first area of the anode.

11. The display device of claim 4, further comprising:
a bank disposed on a part of a top surface of the planarization film excluding the protruding portion.

12. The display device of claim 1, wherein a part of the bank corresponding to the main light-emitting area, a second non-light-emitting area, and a reflection area is open at a left or right side of the main light-emitting area, and only a part of the bank corresponding to the main light-emitting area is open at an upper or lower side of the main light-emitting area.

13. The display device of claim 12, wherein the reflection area is positioned so as to surround the main light-emitting area without overlapping with the main light-emitting area.

14. The display device of claim 2, wherein the organic layer is disposed on top surfaces of the first area and the second area of the anode, the lateral portion and a part of the top surface of the protruding portion, and a top surface and a lateral portion of the bank at a left or right side of the main light-emitting area, and
wherein the organic layer is disposed on the top surface of the first area of the anode and the top surface of the bank at an upper or lower side of the main light-emitting area.

15. The display device of claim 12, wherein the cathode comprises:
a first area disposed in the main light-emitting area; and
a second area extending from the first area of the cathode and corresponding to the lateral portion of the protruding portion.

16. The display device of claim 15, wherein the first area of the cathode has a surface that is substantially parallel to a surface of the substrate, and the second area of the cathode has a surface having a predetermined angle with respect to the substrate.

17. The display device of claim 15, wherein the second area of the cathode is disposed at the left or right side of the main light-emitting area and forms the reflection area.

18. The display device of claim 1, wherein the second area of the anode comprises a second-first area and a second-second area having different thicknesses, and
wherein the second-second area of the anode is positioned outward of the second-first area of the anode.

19. The display device of claim 18, wherein the first area of the anode has a larger thickness than the second-first area of the anode and the second-second area of the anode, and the second-first area of the anode has a larger thickness than the second-second area of the anode.

20. The display device of claim 1, wherein a thickness of the second area of the anode is 64% to 91% of a thickness of the first area of the anode.
